(19) United States
(12) Patent Application Publication
(10) Pub. No.: US 2017/0117875 A1
(43) Pub. Date: Apr. 27, 2017

(54) OSCILLATION MODULE, ELECTRONIC APPARATUS, AND MOVING OBJECT

(71) Applicant: Seiko Epson Corporation, Tokyo (JP)

(72) Inventors: Masataka NOMURA, Minowa (JP); Takuya OWAKI, Minowa (JP)

(21) Appl. No.: 15/333,279

(22) Filed: Oct. 25, 2016

(30) Foreign Application Priority Data
Oct. 26, 2015 (JP) 2015-209937

(51) Int. Cl. H03H 9/64; H03H 9/02

(52) U.S. Cl. CPC H03H 9/64; H03H 9/02559

(57) ABSTRACT

An oscillation module includes a SAW filter and a package adapted to house the SAW filter. One end of the SAW filter is firmly fixed to the package.

This application claims priority to Japanese Patent Application No. 2015-209937 filed on Oct. 26, 2015. The entire disclosure of Japanese Patent Application No. 2015-209937 is hereby incorporated herein by reference.

### BACKGROUND

1. Technical Field

The present disclosure relates to an oscillation module, an electronic apparatus, and a moving object.

2. Related Art

In JP-A-2-290308 (Document 1), there is disclosed an oscillator in which the shapes, arrangement, and wiring between a surface acoustic wave chip and an integrated circuit chip mounted inside the same package are optimized to solve the problem of the oscillation action being unstable due to external electromagnetic induction, parasitic inductance of bonding wires, and so on, and to solve the problem of cross-modulation due to mutual interference between a plurality of oscillators and pull-in oscillation.

However, in the oscillator described in Document 1, a stress is applied on the surface acoustic wave chip due to heat shrinkage of an adhesive necessary to mount the surface acoustic wave chip to the package, and the pitch of an interdigital transducer (IDT) provided to the surface acoustic wave chip slightly changes. As a result, the resonance frequency of the surface acoustic wave chip varies, and therefore, there is a problem that the oscillation signal is deteriorated.

### SUMMARY

An advantage of some aspects of the present disclosure is to provide an oscillation module capable of reducing the deterioration of the oscillation signal due to the stress applied to a SAW filter. Another advantage of some aspects of the present disclosure is to provide an electronic apparatus and a moving object using the oscillation module.

The present disclosure can be implemented as the following aspects or application examples.

### Application Example 1

An oscillation module according to an example application of the present disclosure includes a SAW filter, and a package adapted to house the SAW filter, and one of end parts of the SAW filter is fixed to the package.

According to the example application of the oscillation module, since one of the end parts of the SAW filter is fixed firmly to the package instead of the entire surface of the SAW filter, the area of the part fixed firmly to the package is small, and thus, apart easily deformed by the stress is little. Therefore, according to the oscillation module related to the present application example, the deterioration of the oscillation signal due to the stress applied to the SAW filter can be reduced.

### Application Example 2

For the example application of the oscillation module, the SAW filter may include a first interdigital transducer (IDT), a second IDT, a first input port connected to the first IDT, a second input port connected to the first IDT, a first output port connected to the second IDT, a second output port connected to the second IDT, the first input port, the second input port, the first output port, and the second output port may be disposed in the end part (i.e., the one of the end parts), and the first IDT and the second IDT may be disposed in a part other than the one of the end parts.

According to the oscillation module, even if the end part of the SAW filter that is fixed firmly to the package is deformed by stress, the first IDT and the second IDT not disposed in the end part are hard to deform, and thus, the deterioration of the oscillation signal due to the stress can further be reduced.

Further, according to the example application, since the first input port, the second input port, the first output port, and the second output port, which are robust and hard to be changed in characteristic by deformation, are disposed in the end part of the SAW filter, it is possible to prevent the SAW filter from unnecessarily growing in size to achieve miniaturization of the oscillation module.

### Application Example 3

In the example application of the oscillation module, the first input port, the second input port, the first output port, and the second output port may be arranged along a first side of the SAW filter in a plan view.

According to the example application since all of the four interconnections respectively connected to the first input port, the second input port, the first output port, and the second output port can be disposed around the first side in the outside of the SAW filter, the space in the package can efficiently be used, and thus, the miniaturization of the oscillation module can be achieved.

### Application Example 4

In the example application of the oscillation module, the first input port and the second input port may be disposed at equal distances from the first side, and the first output port and the second output port may be disposed at equal distances from the first side in the plan view.

According to the example application of the oscillation module, it is easy to uniform the length of the interconnection to be connected to the first input port and the length of the interconnection to be connected to the second input port, and it is easy to uniform the length of the interconnection to be connected to the first output port and the length of the interconnection to be connected to the second output port in the outside of the SAW filter. In other words, the length of the interconnection to the first input port and the length of the interconnection to the second input port may be equal. Similarly, the length of the interconnection to the first output port and the length of the interconnection to the second output port in the outside of the SAW filter may be the same.

### Application Example 5

In the example application of the oscillation module, the first input port, the second input port, the first output port, and the second output port may be disposed at equal distances from the first side in the plan view.

According to the example application of the oscillation module, it is easy to uniform the length of the interconnection to be connected to the first input port and the length of the interconnection to be connected to the second input port, and it is easy to uniform the length of the interconnection to be connected to the first output port and the length of the interconnection to be connected to the second output port in the outside of the SAW filter. Further, for example, if the four interconnections to be connected respectively to the first input port, the second input port, the first output port, and the second output port are bonding wires, it is easy to uniform the heights of the bonding wires. Therefore, according to the present application example, the space in the height direction in the package can efficiently be used, and the miniaturization of the oscillation module can be achieved.

### Application Example 6

In the example application of the oscillation module, the first input port, the second input port, the first output port, and the second output port may be arranged in a direction along the first side in the order of the first input port, the first output port, the second output port, and the second input port, or the order of the first output port, the first input port, the second input port, and the second output port in the plan view.

According to the example application of the oscillation module, in the case of arranging the first IDT and the second IDT in a direction along the first side, the first interconnection for connecting the first input port and one electrode of the first IDT, the second interconnection for connecting the second input port and the other electrode of the first IDT, the third interconnection for connecting the first output port and one electrode of the second IDT, and the fourth interconnection for connecting the second output port and the other electrode of the second IDT can be disposed without crossing each other, and thus, the lengths of these interconnections can be shortened.

### Application Example 7

In the example application of the oscillation module, the SAW filter may have a rectangular shape in the plan view, and the first side is a long side.

According to the example application, since it is possible to efficiently use the space around the long side of the SAW filter in the inside of the package to decrease the space around the short side, the miniaturization of the oscillation module can be achieved.

### Application Example 8

In the example application of the oscillation module, the SAW filter may have a rectangular shape in the plan view, and the first side is a short side.

According to the example application, since it is possible to efficiently use the space around the short side of the SAW filter in the inside of the package to decrease the space around the long side, the miniaturization of the oscillation module can be achieved.

### Application Example 9

In the example application of the oscillation module, a length of a first interconnection adapted to connect the first IDT and the first input port and a length of a second interconnection adapted to connect the first IDT and the second input port may be substantially equal to each other.

According to the example application, it is possible to reduce the deviation of the phase difference of a pair of signals input from the first input port and the second input port to the first IDT.

### Application Example 10

In the example application of the oscillation module, a length of a third interconnection adapted to connect the second IDT and the first output port and a length of a fourth interconnection adapted to connect the second IDT and the second output port may be substantially equal to each other.

According to the example application, it is possible to reduce the deviation of the phase difference of a pair of signals output from the second IDT via the first output port and the second output port.

### Application Example 11

The example application of the oscillation module, may further include an integrated circuit to be connected to the SAW filter, and at least a part of the SAW filter overlaps the integrated circuit in a plan view.

According to the example application, since the space in the package can efficiently be used by disposing the integrated circuit in a space below or above the SAW filter, the miniaturization of the oscillation module can be achieved.

### Application Example 12

In the example application of the oscillation module, the SAW filter may overlap the integrated circuit in a part other than the end part in a plan view.

According to the example application, since the space in the package can efficiently be used by disposing the integrated circuit in a space below or above the SAW filter where the SAW filter is not fixed to the package, the miniaturization of the oscillation module can be achieved.

### Application Example 13

An electronic apparatus according to this example application includes any one of the oscillation modules described above.

### Application Example 14

A moving object according to this example application includes any one of the oscillation modules described above.

According to these example applications, since there is provided the oscillation module capable of reducing the deterioration of the oscillation signal due to the stress applied to the SAW filter, for example, the electronic apparatus and the moving object high in reliability can also be realized.

### BRIEF DESCRIPTION OF THE DRAWINGS

The present disclosure will be described with reference to the accompanying drawings, wherein like numbers reference like elements.

FIG. 1 is a perspective view of an oscillation module 1 according to an embodiment of the present disclosure.

FIG. 2 is a cross-sectional view of the oscillation module 1 cut along the line A-A′ shown in FIG. 1.

FIG. 3 is a cross-sectional view of the oscillation module 1 cut along the line B-B′ shown in FIG. 1.

FIG. 4 is a plan view of a SAW filter 2 and an integrated circuit 3.

FIG. 5 is an explanatory diagram of an effect of the oscillation module 1 according to the embodiment.

FIG. 6 is a block diagram showing an example of a functional configuration of the oscillation module 1 according to the embodiment.

FIG. 7 is a diagram showing an example of a circuit configuration of a differential amplifier 20.

FIG. 8 is a diagram showing an example of input and output waveforms of the SAW filter 2.

FIG. 9 is a diagram showing an example of a circuit configuration of a differential amplifier 40.

FIG. 10 is a diagram showing an example of a circuit configuration of a multiplier circuit 60.

FIG. 11 is a diagram showing an example of a circuit configuration of a high-pass filter 70.

FIG. 12 is a diagram showing an example of the frequency characteristic of the high-pass filter 70.

FIG. 13 is a diagram showing an example of a circuit configuration of an output circuit 80.

FIG. 14 is a diagram showing an example of a layout arrangement of the integrated circuit 3.

FIG. 15 is a diagram showing a partial enlarged view of the layout arrangement of the integrated circuit 3.

FIG. 16 is a plan view of the SAW filter 2 in a modified example.

FIG. 17 is a plan view of the SAW filter 2 in another modified example.

FIG. 18 is a plan view of the SAW filter 2 in another modified example.

FIG. 19 is a functional block diagram showing an example configuration of an electronic apparatus 300 according to an embodiment of the present disclosure.

FIG. 20 is a diagram showing an example of a moving object 400 according to an embodiment of the present disclosure.

### DESCRIPTION OF EXEMPLARY EMBODIMENTS

Some preferred embodiments of the present disclosure will hereinafter be described in detail using the accompanying drawings. It should be noted that the embodiments described below do not unreasonably limit the content of the present disclosure as set forth in the appended claims. Further, all of the constituents described below are not necessarily essential elements of the present disclosure.

### 1. Oscillation Module

### 1-1. Structure of Oscillation Module

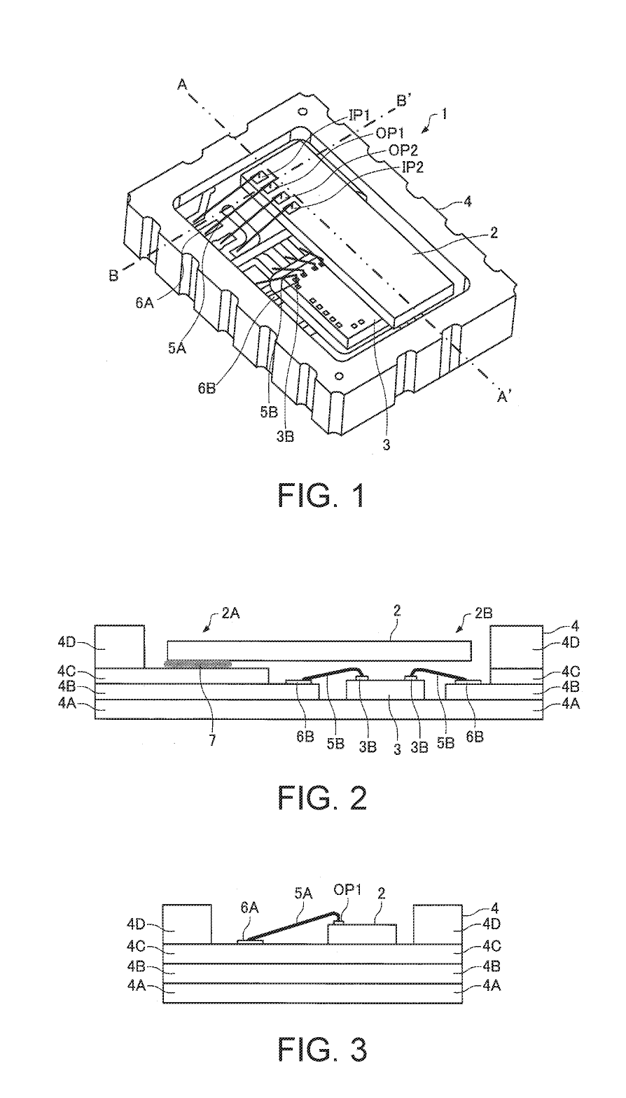

FIG. 1 is a diagram showing an example of a structure of an oscillation module 1 according to the present embodiment, and is a perspective view of the oscillation module 1. Further, FIG. 2 is a cross-sectional view of the oscillation module 1 cut along the line A-A′ shown in FIG. 1, and FIG. 3 is a cross-sectional view of the oscillation module 1 cut along the line B-B′ shown in FIG. 1. It should be noted that, although in FIG. 1 through FIG. 3 there is illustrated the oscillation module 1 in the state in which a lid is removed, in reality, the oscillation module 1 is constituted with an opening of the package 4 covered with the lid not shown.

As shown in FIG. 1, the oscillation module 1 is a surface acoustic wave (SAW) oscillator, and is configured to include a SAW filter (a surface acoustic wave filter) 2, an integrated circuit (IC) 3, and a package 4.

The package 4 is a stacked package, such as a ceramic package, and houses the SAW filter 2 and the integrated circuit 3 in the same space. Specifically, an opening part is provided in an upper part of the package 4, a housing chamber is formed by covering the opening part with a lid (not shown), and the SAW filter 2 and the integrated circuit 3 are housed in the housing chamber.

As shown in FIG. 2, the lower surface of the integrated circuit 3 is bonded and fixed to the upper surface of a first layer 4A of the package 4. Further, electrodes (pads) 3B disposed on the upper surface of the integrated circuit 3 and electrodes 6B disposed on the upper surface of the second layer 4B of the package 4 are respectively bonded to each other with wires 5B.

One of the end parts of the SAW filter 2 is fixed firmly to the package 4. More specifically, the lower surface of one (a first end part) 2A of the end parts in the longitudinal direction of the SAW filter 2 is bonded and fixed to the upper surface of a third layer 4C of the package 4 with an adhesive 7. Further, the other (a second end part) 2B of the end parts in the longitudinal direction of the SAW filter 2 is not fixed, and further, there is provided a gap between the second end part 2B and an inner surface of the package 4. In other words, the SAW filter 2 is fixed to the package 4 to form a cantilever structure.

As shown in FIG. 1, at the first end part 2A on the upper surface of the SAW filter 2, there are disposed four electrodes respectively functioning as a first input port IP1, a second input port IP2, a first output port OP1, and a second output port OP2. Further, as shown in FIG. 1 and FIG. 3, the first input port IP1, the second input port IP2, the first output port OP1, and the second output port OP2 of the SAW filter 2 and four electrodes 6A disposed on the upper surface of the third layer 4C of the package 4 are respectively bonded to each other with wires 5A.

Inside the package 4, there are disposed interconnections (not shown) for electrically connecting the four electrodes 6A and the predetermined four electrodes 6B respectively to each other. Specifically, the first input port IP1, the second input port IP2, the first output port OP1, and the second output OP2 of the SAW filter 2 are respectively connected to the four electrodes (pads) 3B in the integrated circuit 3 different from each other via the wires 5A, the wires 5B, and the internal interconnections of the package 4.

Further, on the surface (outer surface) of the package 4, there is disposed a plurality of external electrodes (not shown) functioning as power supply terminals, ground terminals, or output terminals, and inside the package 4, there are also disposed interconnections (not shown) for electrically connecting the external electrodes and the predetermined electrodes 6B respectively to each other.

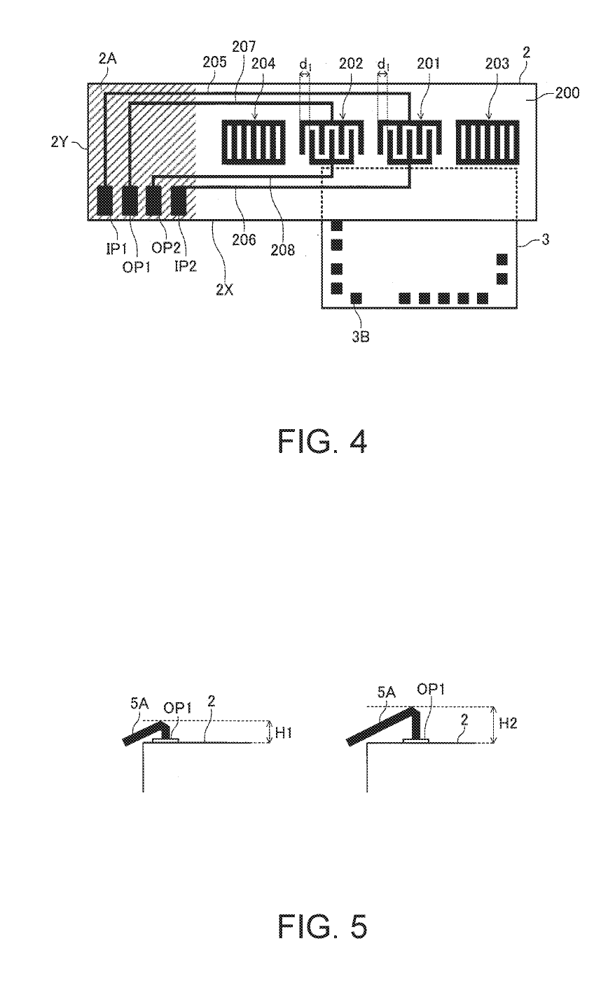

FIG. 4 is a plan view of the SAW filter 2 and the integrated circuit 3 when viewing the oscillation module 1 shown in FIG. 1 from the upper surface thereof.

As shown in FIG. 4, the SAW filter 2 has a first interdigital transducer (IDT) 201, a second IDT 202, a first reflector 203, and a second reflector 204 provided on the surface of the piezoelectric substrate 200.

The piezoelectric substrate 200 can be manufactured using a single-crystal material, such as a quartz crystal, a lithium niobate (LiNbO₃), a lithium tantalate (LiTaO₃), or a lithium tetraborate (Li₂B₄O₇, LBO), a piezoelectric thin film made of a zinc oxide (ZnO), an aluminum nitride (AlN), or the like, or a piezoelectric ceramic material, or the like.

The first IDT 201 and the second IDT 202 are located between the first reflector 203 and the second reflector 204, and each have two electrodes, each of which has a plurality of electrode fingers arranged at regular intervals so that the electrode fingers interdigitate with each other. Further, as shown in FIG. 2, the electrode finger pitches of the first IDT 201 and the second IDT 202 are both set to a constant value d₁.

Further, the SAW filter 2 has the first input port IP1 connected to the first IDT 201, the second input port IP2 connected to the first IDT 201, the first output port OP1 connected to the second IDT 202, and the second output port OP2 connected to the second IDT 202, disposed on the surface of the piezoelectric substrate 200.

Specifically, on the surface of the piezoelectric substrate 200, there are disposed a first interconnection 205 and a second interconnection 206. The first input port IP1 is connected to one (upper one in FIG. 4) of the electrodes of the first IDT 201 with the first interconnection 205, and the second input port IP2 is connected to the other (lower one in FIG. 4) of the electrodes of the first IDT 201 with the second interconnection 206. Further, on the surface of the piezoelectric substrate 200, there are disposed a third interconnection 207 and a fourth interconnection 208. The first output port OP1 is connected to one (upper one in FIG. 4) of the electrodes of the second IDT 202 with the third interconnection 207, and the second output port OP2 is connected to the other (lower one in FIG. 4) of the electrodes of the second IDT 202 with the fourth interconnection 208.

For the SAW filter 2 configured in such a manner, when an electrical signal having a frequency in the vicinity of f=v/(2d₁) (v denotes a speed of the surface acoustic wave propagating on the surface of the piezoelectric substrate 200) is input from the first input port IP1 and the second input port IP2, a surface acoustic wave having a wavelength equal to 2d₁ is excited by the first IDT 201. Then, the surface acoustic wave thus excited by the first IDT 201 is reflected between the first reflector 203 and the second reflector 204 to turn to a standing wave. The standing wave is converted in the second IDT 202 into an electrical signal, and is output from the first output port OP1 and the second output port OP2. In other words, the SAW filter 2 functions as a narrow-band band-pass filter with a center frequency of f=v/(2d₁).

In the present embodiment, as shown in FIG. 4, at least apart of the SAW filter 2 overlaps the integrated circuit 3 in a plan view. Further, in the plan view, the first end part 2A (the part with the hatch shading in FIG. 4) of the SAW filter 2 does not overlap the integrated circuit 3. In the present embodiment, by fixing the first end part 2A of the SAW filter 2 to the package 4 to cantilever the SAW filter 2, and disposing the integrated circuit 3 in the space formed below the SAW filter 2 as described above, miniaturization of the oscillation module 1 is realized.

Further, according to the oscillation module 1 of the present embodiment, since the first end part 2A, which is a part of the surface of the SAW filter 2, is fixed firmly to the package 4 instead of the entire surface of the SAW filter 2, the area of the part fixed firmly is small, and thus, the part easily deformed by the stress applied by the package 4 is small. Therefore, according to the oscillation module 1 of the present embodiment, the deterioration of the oscillation signal due to the stress applied to the SAW filter 2 can be reduced.

Further, since the reverse surface of the piezoelectric substrate 200 in the first end part 2A of the SAW filter 2 is fixed to the package 4 with the adhesive 7, the first end part 2A is easily deformed due to shrinkage of the adhesive 7. Therefore, in the present embodiment, as shown in FIG. 4, the first IDT 201, the second IDT 202, the first reflector 203, and the second reflector 204 are not disposed on the surface of the piezoelectric substrate 200 in the first end part 2A. Thus, the deformation of the first IDT 201 and the second IDT 202 is significantly reduced. Therefore, according to the present embodiment, since it is possible to reduce the error of the electrode finger pitch d₁ with respect to a target value caused by the deformation of the first IDT 201 and the second IDT 202 due to the stress by the shrinkage of the adhesive 7, the oscillation module 1 high in frequency accuracy can be realized.

Further, in the present embodiment, by cantilevering the SAW filter 2, the stress due to the contact with the package 4 is not applied to the second end part 2B, which is a free end. Therefore, according to the present embodiment, since the deformation of the first IDT 201 and the second IDT 202 caused by the stress due to the contact with the package 4 does not occur, it is possible to realize the oscillation module 1 high in frequency accuracy.

Further, in the present embodiment, the first input port IP1, the second input port IP2, the first output port OP1, and the second output port OP2, which are not changed in characteristics by the deformation, are disposed on the surface of the piezoelectric substrate 200 at the first end part 2A of the SAW filter 2. Thus, the SAW filter 2 is prevented from becoming unnecessarily large to make the miniaturization of the oscillation module 1 possible.

Further, in the present embodiment, as shown in FIG. 4, the SAW filter 2 has a rectangular shape having long sides 2X and short sides 2Y. The first input port IP1, the second input port IP2, the first output port OP1, and the second output port OP2 are arranged along the long side 2X (an example of a first side) of the SAW filter 2 in the plan view. Therefore, according to the present embodiment, since all of the four wires 5A connected respectively to the first input port IP1, the second input port IP2, the first output port OP1, and the second output port OP2 can be disposed around the long side 2X in the outside of the SAW filter 2 as shown in FIG. 1, it is possible to efficiently use the space around the long side of the SAW filter 2 in the inside of the package 4 to thereby decrease the space around the short side. Therefore, the oscillation module 1 can be miniaturized.

Further, in the present embodiment, as shown in FIG. 4, the first input port IP1 and the second input port IP2 are arranged with distances equal to each other from the long side 2X, and the first output port OP1 and the second output port OP2 are arranged with distances equal to each other from the long side 2X in the plan view. Therefore, according to the present embodiment, it is possible to make the length of the interconnection (the wire 5A and the substrate interconnection) connected to the first input port IP1 and the length of the interconnection connected to the second input port IP2 uniform, to make the length of the interconnection connected to the first output port OP1 and the length of the interconnection connected to the second output port OP2 uniform, and to reduce the deviation from 180° of a phase difference of the differential signal input to or output from the SAW filter 2.

Further, in the present embodiment, as shown in FIG. 4, the first input port IP1, the second input port IP2, the first output port OP1, and the second output port OP2 are arranged with distances equal to each other from the long side 2X in the plan view. Therefore, it is easy to make the heights of the four wires 5A connected respectively to the first input port IP1, the second input port IP2, the first output port OP1, and the second output port OP2 uniform. In other words, the heights of the four wires 5A may be the same. In particular, in the present embodiment, since the first input port IP1, the second input port IP2, the first output port OP1, and the second output port OP2 are disposed along the long side 2X at positions close to the long side 2X, the height H1 of the highest part of the wire 5A from the upper surface of the SAW filter 2 can be decreased, as shown in the cross-sectional view (the cross-sectional view illustrating a part of FIG. 3) on the left side of FIG. 5. On the right side of FIG. 5, there is shown a cross-sectional view in the case in which the first input port IP1, the second input port IP2, the first output port OP1, and the second output port OP2 are supposedly disposed at positions further from the long side 2X, and the height H2 of the highest part of the wire 5A from the upper surface of the SAW filter 2 is larger than the height H1. As described above, according to the present embodiment, since the wire 5A can be lowered, it becomes possible to reduce the size in the height direction of the package 4, and the miniaturization of the oscillation module 1 can be realized.

Further, in the present embodiment, as shown in FIG. 4, the first input port IP1, the first output port OP1, the second output port OP2, and the second input port IP2 are arranged in the direction along the long side 2X in this order in the plan view. Thus, in the case of arranging the first IDT 201 and the second IDT 202 in the direction along the long side 2X, it becomes easy to dispose the first interconnection 205, the second interconnection 206, the third interconnection 207, and the fourth interconnection 208 without crossing each other, and the lengths of the interconnections can be shortened.

It should be noted that the SAW filter 2 is not limited to the configuration shown in FIG. 4, but can also be, for example, a transversal SAW filter in which the reflectors are not provided and the surface acoustic wave propagates between the IDT for input and the IDT for output.

### 1-2. Functional Configuration of Oscillation Module

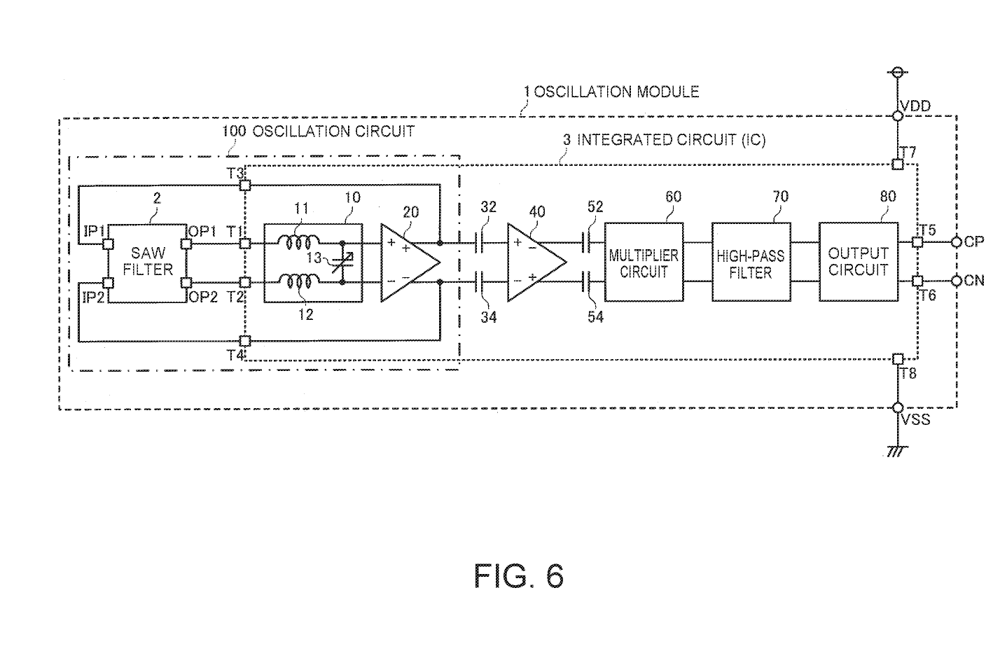

FIG. 6 is a block diagram showing an example of a functional configuration of the oscillation module 1 according to the present embodiment. As shown in FIG. 6, the oscillation module 1 according to the present embodiment is configured to include the SAW filter 2, a phase shift circuit 10, a differential amplifier 20 (a first differential amplifier), a capacitor 32, a capacitor 34, a differential amplifier 40 (a second differential amplifier), a capacitor 52, a capacitor 54, a multiplier circuit 60, a high-pass filter 70 (a filter circuit), and an output circuit 80. It should be noted that the oscillation module 1 according to the present embodiment can be a configuration obtained by arbitrarily eliminating or modifying some of these constituents, or adding other constituents.

The phase shift circuit 10, the differential amplifier 20, the capacitor 32, the capacitor 34, the differential amplifier 40, the capacitor 52, the capacitor 54, the multiplier circuit 60, the high-pass filter 70, and the output circuit 80 are included in the integrated circuit 3. In other words, each of these components is a part of the integrated circuit 3.

The first output port OP1 of the SAW filter 2 is connected to an input terminal T1 of the integrated circuit 3. Further, the second output port OP2 of the SAW filter 2 is connected to an input terminal T2 of the integrated circuit 3. Further, the first input port IP1 of the SAW filter 2 is connected to an output terminal T3 of the integrated circuit 3. Further, the second input port IP2 of the SAW filter 2 is connected to an output terminal T4 of the integrated circuit 3.

A power supply terminal T7 of the integrated circuit 3 is connected to a VDD terminal, which is the external terminal (the external terminal disposed on the surface of the package 4) of the oscillation module 1, and a desired power supply potential is supplied to the power supply terminal T7 via the VDD terminal. Further, a ground terminal T8 of the integrated circuit 3 is connected to a VSS terminal, which is the external terminal of the oscillation module 1, and a ground potential (0V) is supplied to the ground terminal T8 via the VSS terminal. Further, the phase shift circuit 10, the differential amplifier 20, the capacitor 32, the capacitor 34, the differential amplifier 40, the capacitor 52, the capacitor 54, the multiplier circuit 60, the high-pass filter 70, and the output circuit 80 operate using the potential difference between the power supply terminal T7 and the ground terminal T8 as a power supply voltage. It should be noted that the power supply terminals and the ground terminals of the differential amplifier 20, the differential amplifier 40, the multiplier circuit 60, the high-pass filter 70, and the output circuit 80 are connected respectively to the power supply terminal T7 and the ground terminal T8, but are omitted from the illustration in FIG. 6.

The phase shift circuit 10 and the differential amplifier 20 are disposed on a feedback path from the first output port OP1 and the second output port OP2 to the first input port IP1 and the second input port IP2 of the SAW filter 2.

The phase shift circuit 10 has a coil 11 (a first coil), a coil 12 (a second coil), and a variable-capacitance element 13. The inductance of the coil 11 and the inductance of the coil 12 are the same (a difference due to the manufacturing tolerance is allowed) or can also be comparable with each other.

One end of the coil 11 is connected to the input terminal T1 of the integrated circuit 3, and the other end of the coil 11 is connected to one end of the variable-capacitance element 13 and a non-inverting input terminal of the differential amplifier 20. Further, one end of the coil 12 is connected to the input terminal T2 of the integrated circuit 3, and the other end of the coil 12 is connected to the other end of the variable-capacitance element 13 and an inverting input terminal of the differential amplifier 20.

The variable-capacitance element 13 can be, for example, a varactor (also referred to as a varicap or a variable-capacitance diode) varying in capacitance value in accordance with a voltage applied, or can also be a circuit which includes a plurality of capacitors and a plurality of switches for selecting at least a part of the plurality of capacitors, and the capacitance value of which is changed in accordance with the capacitors selected by opening or closing the switches in accordance with selection signals.

The differential amplifier 20 amplifies the potential difference between a pair of signals input to the non-inverting input terminal and the inverting input terminal and then outputs the result from a non-inverted output terminal and an inverted output terminal. The non-inverted output terminal of the differential amplifier 20 is connected to the output terminal T3 of the integrated circuit 3 and one end of the capacitor 32. Further, the inverted output terminal of the differential amplifier 20 is connected to the output terminal T4 of the integrated circuit 3 and one end of the capacitor 34.

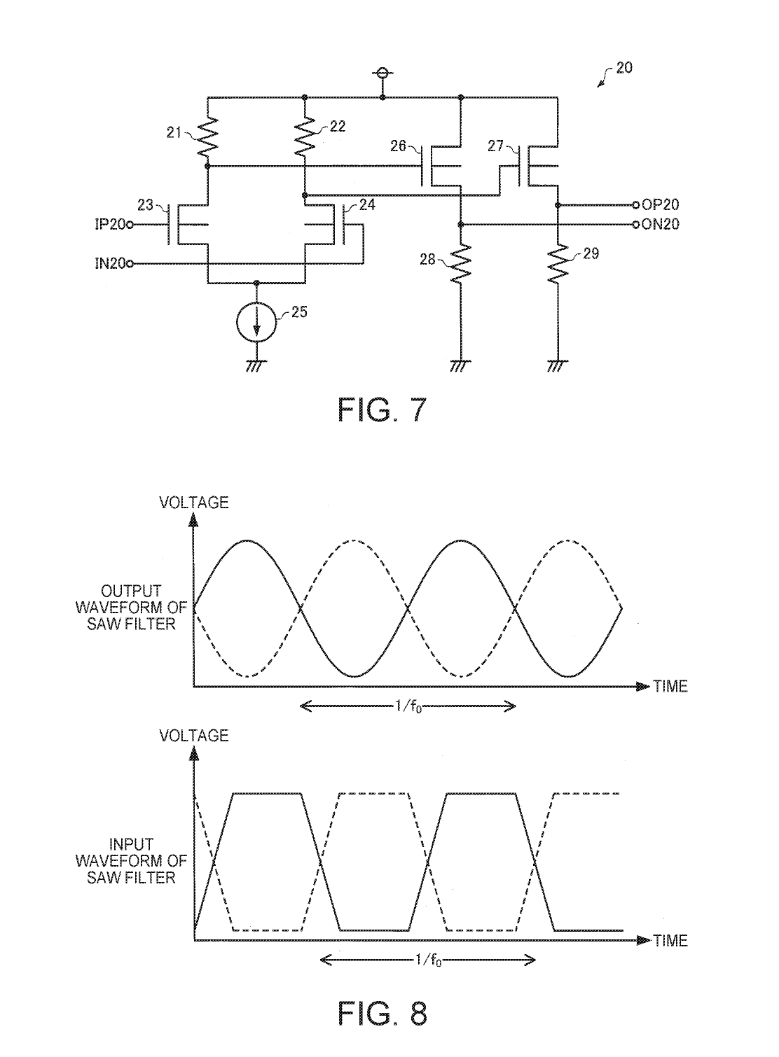

FIG. 7 is a diagram showing an example of a circuit configuration of the differential amplifier 20. In the example shown in FIG. 7, the differential amplifier 20 is configured to include a resister 21, a resister 22, a NMOS (negative-channel metal oxide semiconductor) transistor 23, a NMOS transistor 24, a constant current source 25, a NMOS transistor 26, a NMOS transistor 27, a resistor 28, and a resistor 29. In FIG. 7, for example, an input terminal IP20 is a non-inverting input terminal, and an input terminal IN20 is an inverting input terminal. Further, an output terminal OP20 is a non-inverted output terminal, and an output terminal ON20 is an inverted output terminal.

For the NMOS transistor 23, the gate terminal is connected to the input terminal IP20, the source terminal is connected to one end of the constant current source 25, and the drain terminal is connected to the power supply terminal T7 (see FIG. 6) via the resistor 21.

For the NMOS transistor 24, the gate terminal is connected to the input terminal IN20, the source terminal is connected to one end of the constant current source 25, and the drain terminal is connected to the power supply terminal T7 (see FIG. 6) via the resistor 22.

The other end of the constant current source 25 is connected to the ground terminal T8 (see FIG. 6).

For the NMOS transistor 26, the gate terminal is connected to the drain terminal of the NMOS transistor 23, the source terminal is connected to the ground terminal T8 (see FIG. 6) via the resistor 28, and the drain terminal is connected to the power supply terminal T7 (see FIG. 6).

For the NMOS transistor 27, the gate terminal is connected to the drain terminal of the NMOS transistor 24, the source terminal is connected to the ground terminal T8 (see FIG. 6) via the resistor 29, and the drain terminal is connected to the power supply terminal T7 (see FIG. 6).

Further, the source terminal of the NMOS transistor 26 is connected to the output terminal OP20, and the source terminal of the NMOS transistor 27 is connected to the output terminal ON20.

The differential amplifier 20, configured as described above, non-inversely amplifies a pair of signals input to the input terminal IP20 and the input terminal IN20 and then outputs the result from the output terminal OP20 and the output terminal ON20.

Going back to FIG. 6, in the present embodiment, due to the SAW filter 2, the phase shift circuit 10, and the differential amplifier 20, a pair of signals propagate on the signal path from the first output port OP1 and the second output port OP2 to the first input port IP1 and the second input port IP2 of the SAW filter 2 to form a positive-feedback closed loop, and the pair of signals turn to an oscillation signal. Therefore, the SAW filter 2, the phase shift circuit 10, and the differential amplifier 20 constitute an oscillation circuit 100. It should be noted that the oscillation circuit 100 can have a configuration obtained by arbitrarily eliminating or modifying some of these constituents, or adding other constituents.

In the upper part of FIG. 8, the waveform of the signal (frequency f₀) output from the first output port OP1 of the SAW filter 2 is indicated by the solid line, and the waveform of the signal (frequency f₀) output from the second output port OP2 of the SAW filter 2 is indicated by the dotted line. Further, in the lower part of FIG. 8, the waveform of the signal (frequency f₀) input to the first input port IP1 of the SAW filter 2 is indicated by the solid line, and the waveform of the signal (frequency f₀) input to the second input port IP2 of the SAW filter 2 is indicated by the dotted line.

As shown in FIG. 8, the signal (the solid line) propagating from the first output port OP1 to the first input port IP1 of the SAW filter 2 and the signal (the dotted line) propagating from the second output port OP2 to the second input port IP2 of the SAW filter 2 are reversed in phase from each other. Here, “reversed in phase from each other” is a concept including not only the case in which the phase difference is accurately 180°, but also the case in which, for example, the phase difference is different from 180° as much as the difference in the characteristics between the elements provided to the differential amplifier 20 caused by a difference in length, resistance, and capacitance between the interconnection of the feedback path from the first output port OP1 to the first input port IP1 of the SAW filter 2 and the interconnection of the feedback path from the second output port OP2 to the second input port IP2 of the SAW filter 2.

As described above, the oscillation circuit 100 of the present embodiment amplifies the differential signals (the pair of signals reversed in phase from each other) output from the first output port OP1 and the second output port OP2 of the SAW filter 2 with the differential amplifier 20 and feeds the result back to the first input port IP1 and the second input port IP2 of the SAW filter 2 to thereby constitute the closed-loop feedback path to oscillate. Specifically, the oscillation circuit 100 acts in a differential manner, and oscillates with the frequency f₀ corresponding to the electrode finger pitch d₁ of the first IDT 201 and the second IDT 202.

Further, the power supply noise superimposed on the differential signals, which propagate on the feedback path from the first output port OP1 and the second output port OP2 to the first input port IP1 and the second input port IP2 of the SAW filter 2, via the power supply line is a common-mode noise, and is therefore significantly reduced by the differential amplifier 20. Therefore, according to the oscillation circuit 100, it is possible to reduce the deterioration of the oscillation signal due to the influence of the power supply noise to thereby improve the frequency accuracy and the S/N ratio of the oscillation signal.

Further, the oscillation circuit 100 according to the present embodiment is capable of changing the frequency f₀ of the oscillation signal with a variation corresponding to the inductance of the coil 11 and the inductance of coil 12 within the passband of the SAW filter 2 by varying the capacitance value of the variable-capacitance element 13 of the phase shift circuit 10. The higher the inductance of the coil 11 and the inductance of the coil 12 are, the larger the variation of the frequency f₀ is.

Further, in the oscillation circuit 100 according to the present embodiment, currents having phases reversed from each other flow respectively through the coil 11 and the coil 12. Therefore, since the magnetic field generated by the coil 11 and the magnetic field generated by the coil 12 have directions opposite to each other to weaken each other, the deterioration of the oscillation signal due to the influence of the magnetic fields can be reduced.

Further, in contrast to the fact that a SAW resonator is steep in frequency characteristic with respect to the reactance, the SAW filter 2 is linear (gentle) in frequency characteristic with respect to the reactance. Therefore, the oscillation circuit 100 according to the present embodiment has an advantage that the control of the variation of the frequency f₀ is easy compared to the oscillation circuit using the SAW resonator.

Going back to FIG. 6, in the oscillation module 1, the capacitor 32, the capacitor 34, the differential amplifier 40, the capacitor 52, the capacitor 54, the multiplier circuit 60, the high-pass filter 70, and the output circuit 80 are disposed in the posterior stage of the oscillation circuit 100.

One end of the capacitor 32 is connected to the non-inverted output terminal (the output terminal OP20 in FIG. 7) of the differential amplifier 20, and the other end of the capacitor 32 is connected to the non-inverting input terminal of the differential amplifier 40. Further, one end of the capacitor 34 is connected to the inverted output terminal (the output terminal ON20 in FIG. 7) of the differential amplifier 20, and the other end of the capacitor 34 is connected to the inverting input terminal of the differential amplifier 40. The capacitor 32 and the capacitor 34 function as DC cutting capacitors to remove DC components of the respective signals output from the non-inverted output terminal (the output terminal OP20 in FIG. 7) and the inverted output terminal (the output terminal ON20 in FIG. 7) of the differential amplifier 20.

The differential amplifier 40 is disposed on the signal path from the oscillation circuit 100 to the multiplier circuit 60. The differential amplifier 40 outputs the differential signals, which are obtained by amplifying the differential signals input to the non-inverting input terminal and the inverting input terminal, from a non-inverted output terminal and an inverted output terminal.

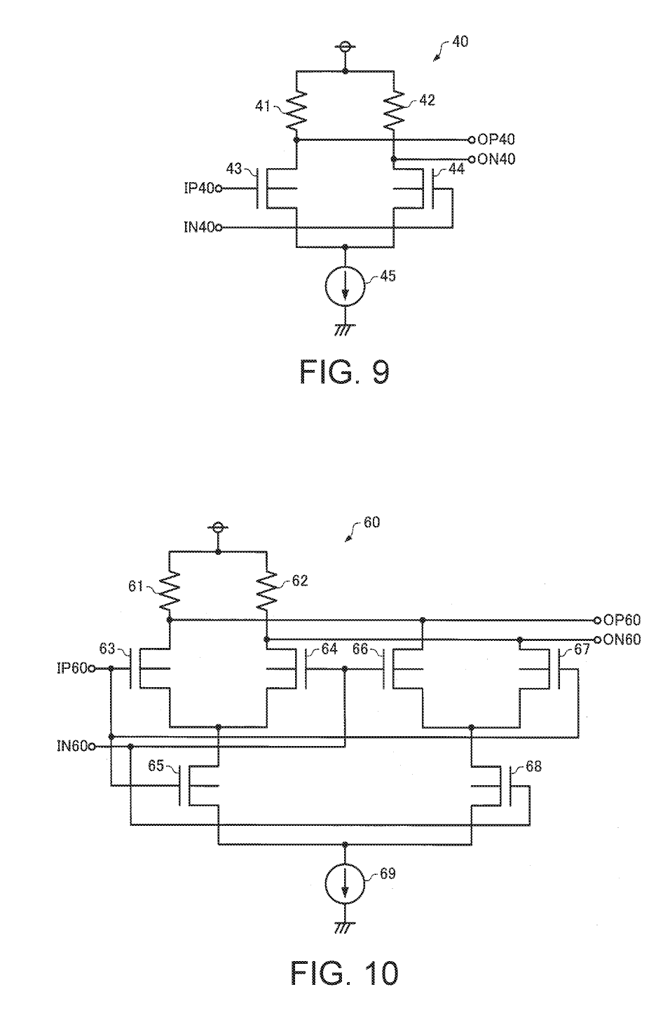

FIG. 9 is a diagram showing an example of a circuit configuration of the differential amplifier 40. In the example shown in FIG. 9, the differential amplifier 40 is configured to include a resistor 41, a resistor 42, a NMOS transistor 43, a NMOS transistor 44, and a constant current source 45. In FIG. 9, for example, an input terminal IP40 is a non-inverting input terminal, and an input terminal IN40 is an inverting input terminal. Further, an output terminal OP40 is a non-inverted output terminal, and an output terminal ON40 is an inverted output terminal.

For the NMOS transistor 43, the gate terminal is connected to the input terminal IP40, the source terminal is connected to one end of the constant current source 45, and the drain terminal is connected to the power supply terminal T7 (see FIG. 6) via the resistor 41.

For the NMOS transistor 44, the gate terminal is connected to the input terminal IN40, the source terminal is connected to one end of the constant current source 45, and the drain terminal is connected to the power supply terminal T7 (see FIG. 6) via the resistor 42.

The other end of the constant current source 45 is connected to the ground terminal T8 (see FIG. 6).

Further, the drain terminal of the NMOS transistor 43 is connected to the output terminal OP40, and the drain terminal of the NMOS transistor 44 is connected to the output terminal ON40.

The differential amplifier 40, configured as described above, non-inversely amplifies differential signals input to the input terminal IP40 and the input terminal IN40, and then outputs the differential signals thus amplified from the output terminal OP40 and the output terminal ON40.

Going back to FIG. 6, one end of the capacitor 52 is connected to the non-inverted output terminal (the output terminal OP40 in FIG. 9) of the differential amplifier 40, and the other end of the capacitor 52 is connected to the non-inverting input terminal of the multiplier circuit 60. Further, one end of the capacitor 54 is connected to the inverted output terminal (the output terminal ON40 in FIG. 9) of the differential amplifier 40, and the other end of the capacitor 54 is connected to the inverting input terminal of the multiplier circuit 60. The capacitor 52 and the capacitor 54 function as DC cutting capacitors to remove DC components of the respective signals output from the non-inverted output terminal (the output terminal OP40 in FIG. 9) and the inverted output terminal (the output terminal ON40 in FIG. 9) of the differential amplifier 40.

The multiplier circuit 60 operates in a differential manner, and outputs the differential signals, which are obtained by multiplying the frequency f₀ of the differential signals input to the non-inverting input terminal and the inverting input terminal, from a non-inverted output terminal and an inverted output terminal.

FIG. 10 is a diagram showing an example of a circuit configuration of the multiplier circuit 60. In the example shown in FIG. 10, the multiplier circuit 60 is configured to include a resistor 61, a resistor 62, a NMOS transistor 63, a NMOS transistor 64, a NMOS transistor 65, a NMOS transistor 66, a NMOS transistor 67, a NMOS transistor 68, and a constant current source 69. In FIG. 10, for example, an input terminal IP60 is a non-inverting input terminal, and an input terminal IN60 is an inverting input terminal. Further, an output terminal OP60 is a non-inverted output terminal, and an output terminal ON60 is an inverted output terminal.

For the NMOS transistor 63, the gate terminal is connected to the input terminal IP60, the source terminal is connected to the drain terminal of the NMOS transistor 65, and the drain terminal is connected to the power supply terminal T7 (see FIG. 6) via the resistor 61.

For the NMOS transistor 64, the gate terminal is connected to the input terminal IN60, the source terminal is connected to the drain terminal of the NMOS transistor 65, and the drain terminal is connected to the power supply terminal T7 (see FIG. 6) via the resistor 62.

For the NMOS transistor 65, the gate terminal is connected to the input terminal IP60, the source terminal is connected to one end of the constant current source 69, and the drain terminal is connected to the source terminal of the NMOS transistor 63 and the source terminal of the NMOS transistor 64.

For the NMOS transistor 66, the gate terminal is connected to the input terminal IN60, the source terminal is connected to the drain terminal of the NMOS transistor 68, and the drain terminal is connected to the power supply terminal T7 (see FIG. 6) via the resistor 61.

For the NMOS transistor 67, the gate terminal is connected to the input terminal IP60, the source terminal is connected to the drain terminal of the NMOS transistor 68, and the drain terminal is connected to the power supply terminal T7 (see FIG. 6) via the resistor 62.

For the NMOS transistor 68, the gate terminal is connected to the input terminal IN60, the source terminal is connected to one end of the constant current source 69, and the drain terminal is connected to the source terminal of the NMOS transistor 66 and the source terminal of the NMOS transistor 67.

The other end of the constant current source 69 is connected to the ground terminal T8 (see FIG. 6).

Further, the drain terminal of the NMOS transistor 63 and the drain terminal of the NMOS transistor 66 are connected to the output terminal OP60, and the drain terminal of the NMOS transistor 64 and the drain terminal of the NMOS transistor 67 are connected to the output terminal ON60.

The multiplier circuit 60, configured as described above, generates differential signals with the frequency 2f₀ twice as high as the frequency f₀ of the differential signals input to the input terminal IP60 and the input terminal IN60. The multiplier circuit 60 outputs the result from the output terminal OP60 and the output terminal ON60. In particular, the multiplier circuit 60 is a balanced modulation circuit, and in principle, has a configuration in which the differential signals (the signals with the frequency f₀) input to the input terminal IP60 and the input terminal IN60 are not output from the output terminal OP60 and the output terminal ON60. According to this multiplier circuit 60, it is possible to reduce the signal component with the frequency f₀ output from the output terminal OP60 and the output terminal ON60 even taking the production tolerance of the NMOS transistors and the resistors into consideration, and the differential signals with the frequency 2f₀ high in purity (high in frequency accuracy) can be obtained, and at the same time, the circuit area is also relatively small.

Going back to FIG. 6, the non-inverted output terminal (the output terminal OP60 in FIG. 10) of the multiplier circuit 60 is connected to a non-inverting input terminal of the high-pass filter 70. Further, the inverted output terminal (the output terminal ON60 in FIG. 10) of the multiplier circuit 60 is connected to an inverting input terminal of the high-pass filter 70.

The high-pass filter 70 is disposed on the signal path from the multiplier circuit 60 to the output circuit 80. For example, the high-pass filter 70 is positioned between the multiplier circuit 60 and the output circuit 80. The high-pass filter 70 operates in a differential manner and outputs the differential signals, which are obtained by attenuating the low-frequency component of the differential signals input to the non-inverting input terminal and the inverting input terminal, from a non-inverted output terminal and an inverted output terminal.

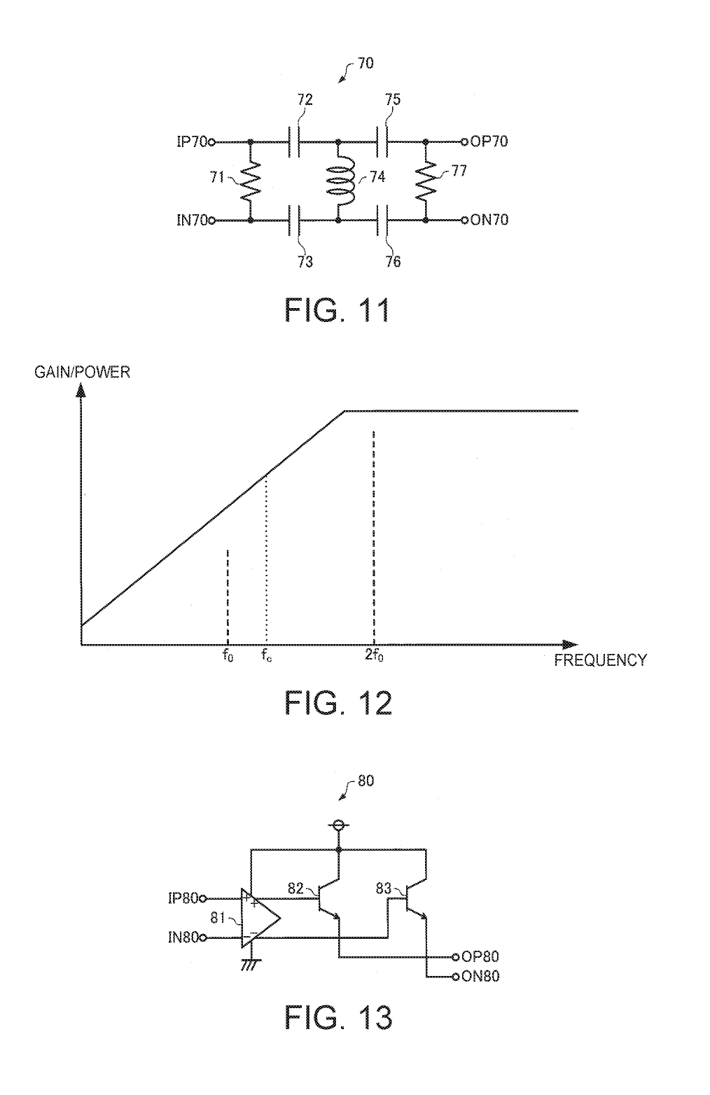

FIG. 11 is a diagram showing an example of a circuit configuration of the high-pass filter 70. In the example shown in FIG. 11, the high-pass filter 70 is configured to include a resistor 71, a capacitor 72, a capacitor 73, a coil 74 (a third coil), a capacitor 75, a capacitor 76, and a resistor 77. In FIG. 11, for example, an input terminal IP70 is a non-inverting input terminal, and an input terminal IN70 is an inverting input terminal. Further, an output terminal OP70 is a non-inverted output terminal, and an output terminal ON70 is an inverted output terminal.

One end of the resistor 71 is connected to the input terminal IP70 and one end of the capacitor 72, and the other end of the resistor 71 is connected to the input terminal IN70 and one end of the capacitor 73.

One end of the capacitor 72 is connected to the input terminal IP70 and one end of the resistor 71, and the other end of the capacitor 72 is connected to one end of the coil 74 and one end of the capacitor 75.

One end of the capacitor 73 is connected to the input terminal IN70 and the other end of the resistor 71, and the other end of the capacitor 73 is connected to the other end of the coil 74 and one end of the capacitor 76.

The one end of the coil 74 is connected to the other end of the capacitor 72 and one end of the capacitor 75, and the other end of the coil 74 is connected to the other end of the capacitor 73 and one end of the capacitor 76.

The one end of the capacitor 75 is connected to the other end of the capacitor 72 and the one end of the coil 74, and the other end of the capacitor 75 is connected to one end of the resistor 77.

The one end of the capacitor 76 is connected to the other end of the capacitor 73 and the other end of the coil 74, and the other end of the capacitor 76 is connected to the other end of the resistor 77.

The one end of the resistor 77 is connected to the other end of the capacitor 75, and the other end of the resistor 77 is connected to the other end of the capacitor 76.

Further, the other end of the capacitor 75 and the one end of the resistor 77 are connected to the output terminal OP70, and the other end of the capacitor 76 and the other end of the resistor 77 are connected to the output terminal ON70.

The high-pass filter 70, configured as described above, generates the differential signals, which are obtained by attenuating the low-frequency component of the differential signals input to the input terminal IP70 and the input terminal IN70, and then outputs the result from the output terminal OP70 and the output terminal ON70.

FIG. 12 is a diagram showing an example of the frequency characteristic of the high-pass filter 70. In FIG. 12, the frequency spectrum of the output signal of the multiplier circuit 60, which is the input signal of the high-pass filter 70, is also illustrated with the dotted lines. In FIG. 12, the horizontal axis represents the frequency, and the vertical axis represents the gain (in the case of the frequency characteristic of the high-pass filter 70) or the power (in the case of the frequency spectrum of the output signal of the multiplier circuit 60). As shown in FIG. 12, the resistance values of the respective resistors, the capacitance values of the respective capacitors, and the inductance value of the coil 74 are set so that the cutoff frequency f_{c} of the high-pass filter 70 takes a value between f₀ and 2f₀. As described above, although the multiplier circuit 60 outputs the differential signals with the frequency 2f₀ high in purity (high in frequency accuracy) and small in signal component of f₀, since the signal component of f₀ lower than the cutoff frequency f_{c} is attenuated by the high-pass filter 70 as shown in FIG. 12, the differential signals with the frequency 2f₀ higher in purity (higher in frequency accuracy) can be obtained.

Going back to FIG. 6, the non-inverted output terminal (the output terminal OP70 in FIG. 11) of the high-pass filter 70 is connected to a non-inverting input terminal of the output circuit 80. Further, the inverted output terminal (the output terminal ON70 in FIG. 11) of the high-pass filter 70 is connected to an inverting input terminal of the output circuit 80.

The output circuit 80 is disposed in the posterior stage of the multiplier circuit 60 and the high-pass filter 70. The output circuit 80 operates in a differential manner, generates the differential signals, which are obtained by converting the differential signals input to the non-inverting input terminal and the inverting input terminal into signals having desired voltage levels (or current levels), and outputs the result from a non-inverted output terminal and an inverted output terminal. The non-inverted output terminal of the output circuit 80 is connected to an output terminal T5 of the integrated circuit 3, and the inverted output terminal of the output circuit 80 is connected to an output terminal T6 of the integrated circuit 3. The output terminal T5 of the integrated circuit 3 is connected to a CP terminal as the external terminal of the oscillation module 1, and the output terminal T6 of the integrated circuit 3 is connected to a CN terminal as the external terminal of the oscillation module 1. Further, the differential signals (the oscillation signals) converted by the output circuit 80 are output to the outside from the CP terminal and the CN terminal of the oscillation module 1 via the output terminal T5 and the output terminal T6 of the integrated circuit 3.

FIG. 13 is a diagram showing an example of a circuit configuration of the output circuit 80. In the example shown in FIG. 13, the output circuit 80 is configured to include a differential amplifier 81, a NPN transistor 82, and a NPN transistor 83. In FIG. 13, for example, an input terminal IP80 is a non-inverting input terminal, and an input terminal IN80 is an inverting input terminal. Further, an output terminal OP80 is a non-inverted output terminal, and an output terminal ON80 is an inverted output terminal.

In the differential amplifier 81, the non-inverting input terminal is connected to the input terminal IP80, the inverting input terminal is connected to the input terminal IN80, the non-inverted output terminal is connected to the base terminal of the NPN transistor 82, the inverted output terminal is connected to the base terminal of the NPN transistor 83, and the differential amplifier 81 operates with the power supply voltage VDD supplied from the power supply terminal T7 (see FIG. 6) and the ground terminal T8.

For the NPN transistor 82, the base terminal is connected to the non-inverted output terminal of the differential amplifier 81, the collector terminal is connected to the power supply terminal T7 (see FIG. 6), and the emitter terminal is connected to the output terminal OP80.

For the NPN transistor 83, the base terminal is connected to the inverted output terminal of the differential amplifier 81, the collector terminal is connected to the power supply terminal T7 (see FIG. 6), and the emitter terminal is connected to the output terminal ON80.

The output circuit 80, configured as described above, is a PECL (positive emitter coupled logic) circuit or a LV-PECL (low-voltage positive emitter coupled logic) circuit, and by pulling down the output terminal OP80 and the output terminal ON80 to a predetermined potential V1, the output circuit 80 converts the differential signals input from the input terminal IP80 and the input terminal IN80 into differential signals, the high level of which is defined as VDD-V_{CE}, and the low level of which is defined as V1, and then outputs the result from the output terminal OP80 and the output terminal ON80. It should be noted that V_{CE} denotes the voltage between the collector and the emitter of the NPN transistor 82 or the NPN transistor 83.

According to the oscillation module 1 related to the present embodiment described hereinabove, even if the noise is superimposed on the power supplied to the circuits (the differential amplifier 40, the multiplier circuit 60, the high-pass filter 70, and the output circuit 80) in the posterior stage of the oscillation circuit 100 due to the operation of the oscillation circuit 100, since all of the circuits operate in a differential manner, the power supply noise to be superimposed on the differential signals (the oscillation signals) output by the respective circuits becomes a common-mode noise. Therefore, according to the oscillation module 1 related to the present embodiment, it is possible to output the oscillation signals, in which the deterioration due to the influence of the power supply noise generated by the operation of the oscillation circuit 100 is reduced.

Further, according to the oscillation module 1 related to the present embodiment, since the multiplier circuit 60 is disposed in the posterior stage of the oscillation circuit 100, it is possible to output the oscillation signals with the frequency obtained by multiplying the frequency of the oscillation signals output by the oscillation circuit 100.

Further, according to the oscillation module 1 related to the present embodiment, since the oscillation circuit 100 operates in a differential manner, the power supply noise superimposed as the common-mode noise on the differential signals (the oscillation signals) propagating on the feedback path in the oscillation circuit 100 is dramatically reduced. Therefore, according to the oscillation module 1 related to the present embodiment, the frequency accuracy and the S/N ratio of the oscillation signals can be improved.

Further, according to the oscillation module 1 related to the present embodiment, since the multiplier circuit 60 is the balanced modulation circuit, in principle, the signals the same in frequency as the signal input to the multiplier circuit 60 are not output from the multiplier circuit 60 (only the signals obtained by multiplying the frequency of the signals to be input are output). Therefore, according to the oscillation module 1 related to the present embodiment, the oscillation signals high in frequency accuracy can be obtained.

Further, in the oscillation module 1 according to the present embodiment, the oscillation circuit 100 outputs the differential signals, and the circuits (the differential amplifier 40, the multiplier circuit 60, and the high-pass filter 70) located along the signal path from the oscillation circuit 100 to the output circuit 80 operate in a differential manner. Since the power supply noise generated by the operation of the oscillation circuit 100 is superimposed as a common-mode noise on the differential signals input to the respective circuits via the power supply line, it is possible for the circuits to output the differential signals with the power supply noise reduced dramatically by operating in a differential manner. The power supply noise (the common-mode noise) superimposed on the input signal of the output circuit 80 via the power supply line is also reduced dramatically in a similar manner by the output circuit 80 operating in a differential manner. As described above, according to the oscillation module 1 related to the present embodiment, it is possible to output the oscillation signals high in frequency accuracy, in which the deterioration due to the influence of the power supply noise generated by the operation of the oscillation circuit 100 is reduced.

Further, according to the oscillation module 1 related to the present embodiment, by appropriately selecting the gain of the differential amplifier 20 provided to the oscillation circuit 100 and the gain of the differential amplifier 40 disposed in the posterior stage of the oscillation circuit 100, it is possible to optimally design the frequency accuracy of the oscillation signals. Further, according to the oscillation module 1 related to the present embodiment, since the signals with an unwanted frequency component included in the oscillation signals output by the multiplier circuit 60 can be reduced by the high-pass filter 70, it is possible to improve the frequency accuracy of the oscillation signals.

### 1-3. Layout of Integrated Circuit

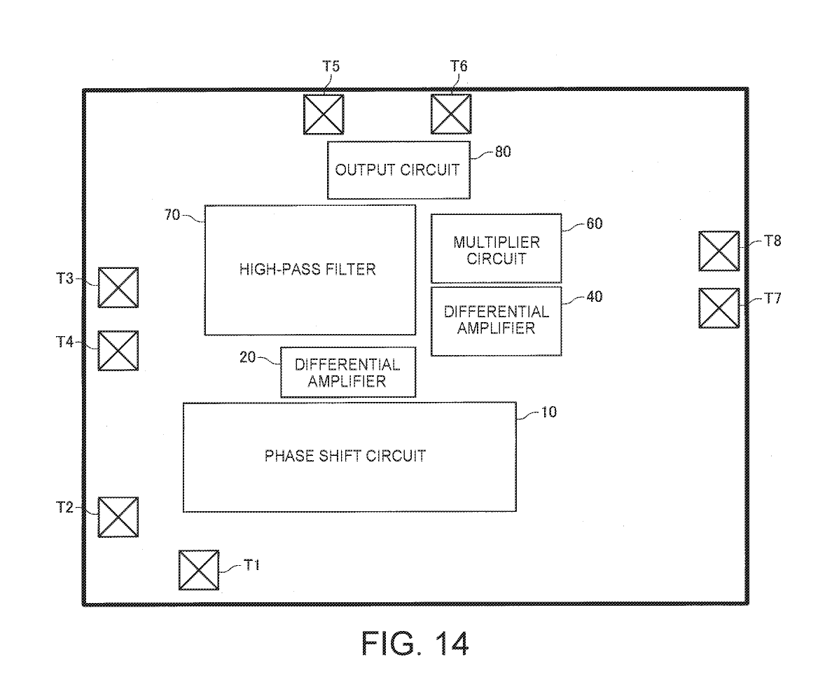

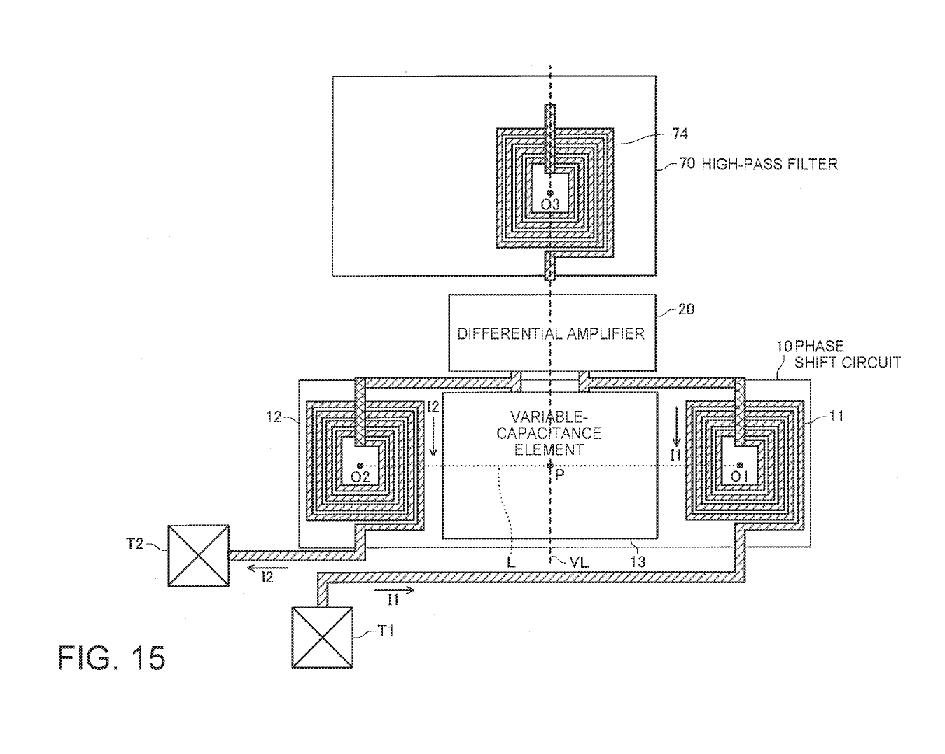

In the oscillation module 1 according to the present embodiment, in order to improve the frequency accuracy of the differential signal output from the integrated circuit 3, the layout of the integrated circuit 3 is devised. FIG. 14 is a diagram showing an example of the layout arrangement of the circuits (some are omitted) included in the integrated circuit 3. FIG. 14 is a plan view of the integrated circuit 3 viewed from a direction perpendicular to the surface of the semiconductor substrate on which the variety of elements (e.g., transistors and resistors) are stacked. Further, FIG. 15 is a diagram obtained by enlarging a part including the input terminal T1, the input terminal T2, the phase shift circuit 10, the differential amplifier 20, and the high-pass filter 70 out of the layout arrangement plan shown in FIG. 14. FIG. 15 also shows the layout arrangement of the coil 11, the coil 12, and the variable-capacitance element 13 included in the phase shift circuit 10, the coil 74 included in the high-pass filter 70, and some wiring patterns.

In FIG. 15, the imaginary straight line VL is a straight line passing through the midpoint P between the center O1 of the coil 11 and the center O2 of the coil 12. The imaginary straight line VL is perpendicular to the line segment L connecting the center O1 of the coil 11 and the center O2 of the coil 12 to each other. In other words, the imaginary straight line VL is a straight line equally distant from the center O1 of the coil 11 and the center O2 of the coil 12.

In the present embodiment, as shown in FIG. 15, the differential amplifier 20 and the variable-capacitance element 13 are arranged so as to cross the imaginary straight line VL equally distant from the center O1 of the coil 11 and the center O2 of the coil 12 in the plan view of the integrated circuit 3. Due to such a layout arrangement as described above, it is possible to decrease the difference between the length of the interconnection for connecting the other end of the coil 11 and the non-inverting input terminal of the differential amplifier 20 to each other and the length of the interconnection for connecting the other end of the coil 12 and the inverting input terminal of the differential amplifier 20 to each other. Similarly, it is possible to decrease the difference between the length of the interconnection for connecting the one end of the variable-capacitance element 13 and the non-inverting input terminal of the differential amplifier 20 to each other and the length of the interconnection for connecting the other end of the variable-capacitance element 13 and the inverting input terminal of the differential amplifier 20 to each other. Therefore, the difference in parasitic capacitance and parasitic resistance between the signal path from the other end of the coil 11 to the non-inverting input terminal of the differential amplifier 20 and the signal path from the other end of the coil 12 to the inverting input terminal of the differential amplifier 20 is decreased, and it is possible to decrease the deviation from 180° of the phase difference of the differential signals propagating through these two signal paths, and the difference in the level of the noise superimposed on the differential signals. Therefore, the frequency accuracy and the S/N ratio of the oscillation signals output by the oscillation circuit 100 can be improved.

In the present embodiment, as shown in FIG. 15, the coil 74 is arranged so as to cross the imaginary straight line VL equally distant from the center O1 of the coil 11 and the center O2 of the coil 12 in the plan view of the integrated circuit 3. As shown in FIG. 15, the coil 74 can also be arranged so that the center O3 is located on the imaginary straight line VL. Assuming that the wiring pattern of the coil 11 and the wiring pattern of the coil 12 are the same, the current I1 flowing through the coil 11 and the current 12 flowing through the coil 12 are opposite in direction to (reversed in phase from) each other. Specifically, when the current I1 flows clockwise through the coil 11, the current I2 flows counterclockwise through the coil 12, and when the current I1 flows counterclockwise through the coil 11, the current I2 flows clockwise through the coil 12. Therefore, on the imaginary straight line VL, the direction of the magnetic field generated by the coil 11 and the direction of the magnetic field generated by the coil 12 are opposite to each other, and thus the magnetic fields weaken each other. Further, if the wiring pattern of the coil 11 and the wiring pattern of the coil 12 are the same as each other, ideally, the inductance of the coil 11 and the inductance of the coil 12 are equal to each other, and the current I1 and the current I2 are equal in amount to each other. Since the difference between the inductance of the coil 11 and the inductance of the coil 12, and the difference in amount between the current I1 and the current I2 are small, it results that on the imaginary straight line VL, the strength of the magnetic field generated by the coil 11 and the strength of the magnetic field generated by the coil 12 are roughly equal to each other, and therefore cancel each other out. Therefore, it is possible to lower the level of the signals with the frequency f₀ to be superimposed on the signals with the frequency 2f₀ output by the high-pass filter 70 due to the magnetic field coupling between the coil 74 disposed so as to cross the imaginary straight line VL and the coils 11, 12, and thus, it is possible for the oscillation module 1 to output the oscillation signals high in frequency accuracy.

Further, in the present embodiment, as shown in FIG. 15, the variable-capacitance element 13 is disposed between the coil 11 and the coil 12 in the plan view of the integrated circuit 3. By disposing the variable-capacitance element 13, which is hard to be affected by the magnetic field, in an area between the coil 11 and the coil 12 which is affected by the magnetic fields generated by the coil 11 and by the coil 12, an unnecessary increase in the layout area can be suppressed. Further, since the interconnection for connecting the other end of the coil 11 and the one end of the variable-capacitance element 13, and the interconnection for connecting the other end of the coil 12 and the other end of the variable-capacitance element 13 are both shortened, it is possible to reduce the layout area, and at the same time reduce the parasitic capacitance and the parasitic resistance of these interconnections.

Further, in the present embodiment, as shown in FIG. 15, the differential amplifier 20 is disposed between the variable-capacitance element 13 and the coil 74 in the plan view of the integrated circuit 3. Due to such a layout arrangement, since the distance between the coil 11 and the coil 74 and the distance between the coil 12 and the coil 74 can be increased as much as the size of the differential amplifier 20 while preventing an unnecessary increase in the layout area, the intensity of the magnetic field from the coil 11 and the intensity of the magnetic field from the coil 12 received by the coil 74 may decrease. Therefore, it is possible to further lower the level of the signals with the frequency f₀ to be superimposed on the signals with the frequency 2f₀ output by the high-pass filter 70 due to the magnetic field coupling between the coils 11, 12 and the coil 74, and thus, it is possible for the oscillation module 1 to output the oscillation signals higher in frequency accuracy.

Further, by shortening the distance between the variable-capacitance element 13 and the differential amplifier 20, the interconnection for connecting the other end of the coil 11 and the non-inverting input terminal of the differential amplifier 20, and the interconnection for connecting the other end of the coil 12 and the inverting input terminal of the differential amplifier 20 are both shortened as a result. Therefore, the layout area can be reduced, and at the same time, the parasitic capacitance and the parasitic resistance of the signal path from the other end of the coil 11 to the non-inverting input terminal of the differential amplifier 20 and the parasitic capacitance and the parasitic resistance of the signal path from the other end of the coil to the inverting input terminal of the differential amplifier 20 are all decreased. Further, it is possible to decrease the deviation from 180° of the phase difference of the differential signals propagating through these two signal paths, and the level of the noise superimposed on the differential signals.

Further, in the present embodiment, as shown in FIG. 15, the distance (e.g., center distance) between the coil 11 and the input terminal T1 (a first pad) connected to the coil 11 with the interconnection is shorter than the distance (e.g., center distance) between the coil 74 and the input terminal T1. Further, the distance (e.g., center distance) between the coil 12 and the input terminal T2 (a second pad) connected to the coil 12 with the interconnection is shorter than the distance (e.g., center distance) between the coil 74 and the input terminal T2. Due to such a layout arrangement, since the interconnection for connecting the input terminal T1 and the coil 11 and the interconnection for connecting the input terminal T2 and the coil 12 are shortened, it is possible to reduce the layout area, and at the same time reduce the parasitic capacitance and the parasitic resistance of these interconnections. Therefore, the parasitic capacitance and the parasitic resistance of the signal path from the input terminal T1 to the one end of the coil 11 and the parasitic capacitance and the parasitic resistance of the signal path from the input terminal T2 to the one end of the coil 12 are all decreased, and it is possible to decrease the deviation from 180° of the phase difference of the differential signals propagating through these two signal paths, and the level of the noise superimposed on the differential signals.

Further, due to such a layout arrangement, the distance between the input terminal T1 and the coil 74 and the distance between the input terminal T2 and the coil 74 (i.e., the output terminals of the high-pass filter 70) become longer. Therefore, it is possible to reduce the possibility that the frequency component f₀ of the current flowing through the coil 11 and the coil 12 is coupled via the input terminal T1 and the input terminal T2 to the current with the frequency 2f₀ flowing through the coil 74. In other words, it is hard for the signals with the frequency f₀ input to the input terminal T1 and the input terminal T2 to be superimposed on the signals with the frequency 2f₀ output by the high-pass filter 70, and it is possible for the oscillation module 1 to output the oscillation signals high in frequency accuracy.

Further, in the present embodiment, as shown in FIG. 14, the differential amplifier 40 is disposed in the vicinity of the differential amplifier 20, the multiplier circuit 60 is disposed at a position close to both of the differential amplifier 40 and the high-pass filter 70, the output circuit 80 is disposed in the vicinity of the high-pass filter 70, and the output terminal T5 and the output terminal T6 are disposed in the vicinity of the output circuit 80. Due to such a layout configuration, it is possible to shorten each of the interconnections for connecting the circuits. Therefore, it is possible to reduce the layout area of the integrated circuit 3, and at the same time to decrease the deviation from 180° of the phase difference of the differential signals propagating from the input terminal T1 and the input terminal T2 to the output terminal T5 and the output terminal T6, and to lower the level of the noise to be superimposed on the differential signals.

As described hereinabove, according to the oscillation module 1 related to the present embodiment, since the layout arrangement shown in FIG. 14 and FIG. 15 is adopted, both of a decrease in the layout area (decrease in size) of the integrated circuit 3 and output of the differential signals high in frequency accuracy can be achieved.

### 1-4. Modified Examples

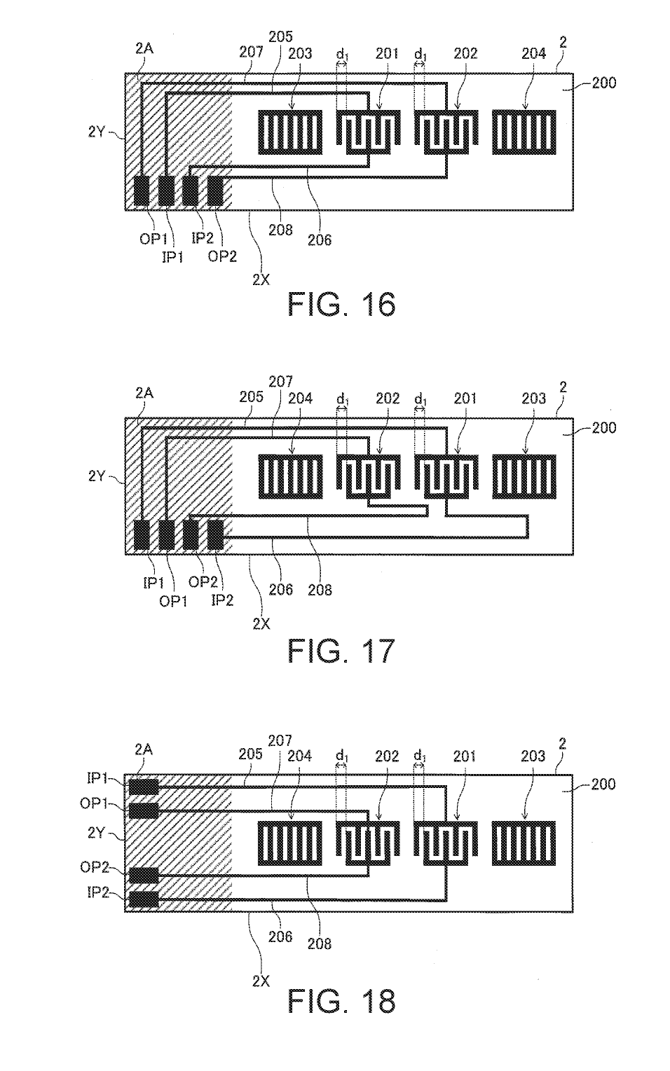

Although in the embodiment described above, as shown in FIG. 4, in the SAW filter 2, the first input port IP1, the first output port OP1, the second output port OP2, and the second input port IP2 are arranged in this order in the direction along the long side 2X in the plan view, the first output port OP1, the first input port IP1, the second input port IP2, and the second output port OP2 can also be arranged in this order in the direction along the long side 2X as shown in FIG. 16. In this case, as shown in FIG. 16, by exchanging the positions of the first IDT 201 and the second IDT 202 with respect to the case shown in FIG. 4, and exchanging the positions of the first reflector 203 and the second reflector 204 with respect to the case shown in FIG. 4, it becomes easy to dispose the first interconnection 205, the second interconnection 206, the third interconnection 207, and the fourth interconnection 208 without crossing each other, and the lengths of the interconnections can be shortened.

Further, as shown in FIG. 17, in the SAW filter 2, at least one of the first interconnection 205 and the second interconnection 206 can be folded back so that the length of the first interconnection 205 for connecting the first IDT 201 and the first input port IP1 and the length of the second interconnection 206 for connecting the first IDT 201 and the second input port IP2 become substantially equal to each other. According to the present modified example, it is possible to decrease the deviation from 180° of the phase difference of the differential signals input to the first IDT 201 from the first input port IP1 and the second input port IP2.

Further, as shown in FIG. 17, in the SAW filter 2, at least one of the third interconnection 207 and the fourth interconnection 208 can be folded back so that the length of the third interconnection 207 for connecting the second IDT 202 and the first output port OP1 and the length of the fourth interconnection 208 for connecting the second IDT 202 and the second output port OP2 become substantially equal to each other. According to the present modified example, it is possible to decrease the deviation from 180° of the phase difference of the differential signals output from the second IDT 202 via the first output port OP1 and the second output port OP2.

Further, as shown in FIG. 18, in the SAW filter 2, the first input port IP1, the second input port IP2, the first output port OP1, and the second output port OP2 can also be arranged along the short side 2Y (an example of the first side) of the SAW filter 2 in the plan view. Therefore, according to the present embodiment, since all of the four wires 5A connected respectively to the first input port IP1, the second input port IP2, the first output port OP1, and the second output port OP2 can be disposed around the short side 2Y in the outside of the SAW filter 2, it is possible to efficiently use the space around the short side of the SAW filter 2 in the inside of the package 4 to thereby decrease the space around the long side. Therefore, the oscillation module 1 can be miniaturized.

Further, in the present modified example, as shown in FIG. 18, the first input port IP1 and the second input port IP2 are arranged with distances equal to each other from the short side 2Y, and the first output port OP1 and the second output port OP2 are arranged with distances equal to each other from the short side 2Y in the plan view. Therefore, according to the present modified example, it is possible to make the length of the interconnection (the wire 5A and the substrate interconnections) connected to the first input port IP1 and the length of the interconnection connected to the second input port IP2 easy to uniform, to make the length of the interconnection connected to the first output port OP1 and the length of the interconnection connected to the second output port OP2 easy to uniform, and to reduce the deviation from 180° of a phase difference of the differential signal input to or output from the SAW filter 2.

Further, in the present modified example, as shown in FIG. 18, the first input port IP1, the second input port IP2, the first output port OP1, and the second output port OP2 are arranged with distances equal to each other from the short side 2Y in the plan view. Therefore, it is easy to have uniform heights for the four wires 5A connected respectively to the first input port IP1, the second input port IP2, the first output port OP1, and the second output port OP2. In particular, in the present modified example, since the first input port IP1, the second input port IP2, the first output port OP1, and the second output port OP2 are disposed along the short side 2Y at positions close to the short side 2Y, the height of the wires 5A can be lowered. Therefore, it becomes possible to reduce the size in the height direction of the package 4, and the miniaturization of the oscillation module 1 can be realized.

Further, in the present modified example, as shown in FIG. 18, the first input port IP1, the first output port OP1, the second output port OP2, and the second input port IP2 are arranged in this order in the direction along the short side 2Y in the plan view. Thus, in the case of arranging the first IDT 201 and the second IDT 202 in the direction along the long side 2X, it becomes easy to dispose the first interconnection 205, the second interconnection 206, the third interconnection 207, and the fourth interconnection 208 without crossing each other, and the lengths of the interconnections can be shortened. Further, it is easy to make the length of the first interconnection 205 connected to the first input port IP1 and the length of the second interconnection 206 connected to the second input port IP2 uniform. In addition, it is easy to make the length of the third interconnection 207 connected to the first output port OP1 and the length of the fourth interconnection 208 connected to the second output port OP2 uniform. In other words, the length of the first interconnection 205 connected to the first input port IP1 and the length of the second interconnection 206 connected to the second input port IP2 may be the same. Similarly, the length of the third interconnection 207 connected to the first output port OP1 and the length of the fourth interconnection 208 connected to the second output port OP2 may be the same. Therefore, it is possible to reduce the deviation from 180° of the phase difference of the differential signals input to or output from the SAW filter 2.

Further, although not shown in the drawings, the first output port OP1, the first input port IP1, the second input port IP2, and the second output port OP2 can also be arranged in this order in the direction along the short side 2Y in the plan view. In this case, by exchanging the positions of the first IDT 201 and the second IDT 202 with respect to the case shown in FIG. 18, it becomes easy to dispose the first interconnection 205, the second interconnection 206, the third interconnection 207, and the fourth interconnection 208 without crossing each other, and the lengths of the interconnections can be shortened. Further, it is easy to unify the length of the first interconnection 205 and the length of the second interconnection 206, and it is easy to unify the length of the third interconnection 207 and the length of the fourth interconnection 208. The deviation from 180° of the phase difference of the differential signals input from or output to the SAW filter 2 can be decreased.

Further, in the embodiment described above, by disposing the coil 11 and the coil 12 as members having inductance on the feedback path from the first output port OP1 and the second output port OP2 to the first input port IP1 and the second input port IP2 of the SAW filter 2, the variation of the oscillation frequency is increased. In contrast, it is also possible to dispose other members having inductance on the feedback path instead of the coil 11 and the coil 12, or together with the coil 11 and coil 12. As the member having inductance other than the coil, there can be cited, for example, bonding wires or substrate interconnections, and it is possible for the oscillation circuit 100 to vary the oscillation frequency with the variation corresponding to the inductance value of the bonding wire and the substrate interconnection.

Further, although in the oscillation module 1 according to the present embodiment, the high-pass filter 70, which has the cutoff frequency f_{c} higher than the frequency f₀, and has the passband including the frequency 2f₀, is disposed in the posterior state of the multiplier circuit 60, it is also possible to replace the high-pass filter 70 with a band-pass filter, which has the lower cutoff frequency higher than the frequency f₀ and has the passband including the frequency 2f₀.

Further, although the oscillation module 1 according to the present embodiment includes the oscillation circuit 100 and the circuits in the posterior stage of the oscillation circuit 100, it is also possible to adopt a configuration excluding the circuits in the posterior stage of the oscillation circuit 100.

### 2. Electronic Apparatus

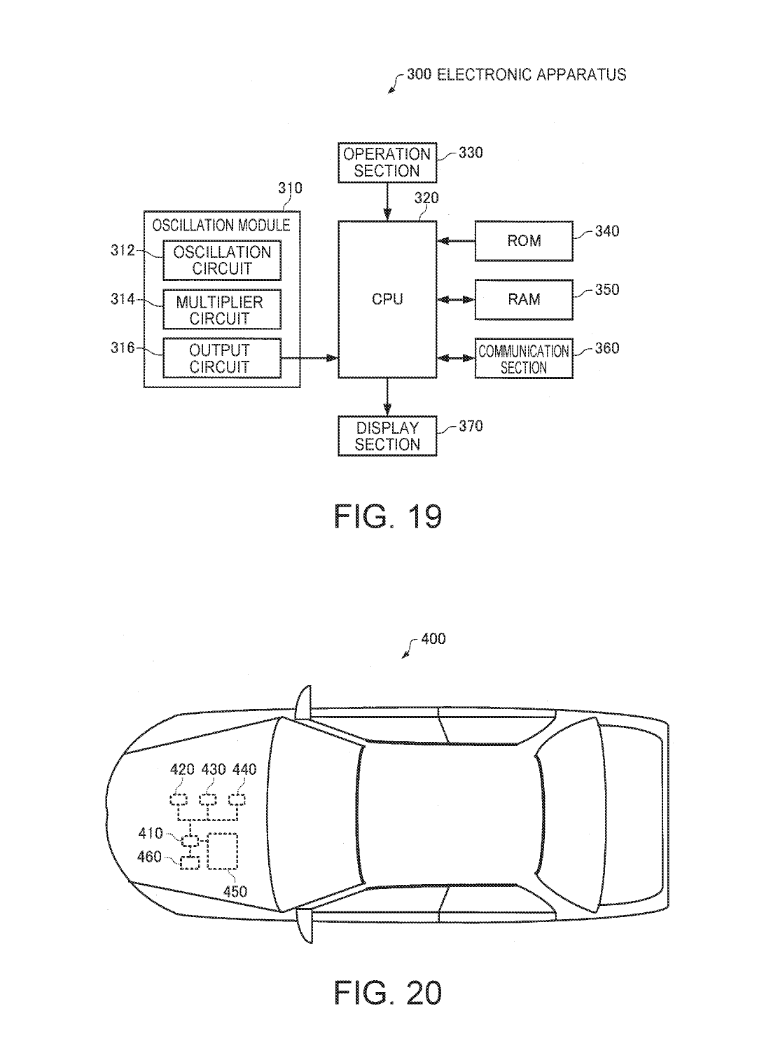

FIG. 19 is a functional block diagram showing an example of a configuration of an electronic apparatus according to the embodiment. The electronic apparatus 300 according to the present embodiment is configured to include an oscillation module 310, a central processing unit (CPU) 320, an operation section 330, a read only memory (ROM) 340, a random access memory (RAM) 350, a communication section 360, and a display section 370. It should be noted that the electronic apparatus according to the present embodiment can be provided with a configuration obtained by eliminating or modifying some of the constituents (sections) shown in FIG. 19, or adding another constituent thereto.

The oscillation module 310 is provided with an oscillation circuit 312. The oscillation circuit 312 is provided with a SAW filter (not shown), and generates an oscillation signal with a frequency based on the resonance frequency of the SAW filter.

Further, the oscillation module 310 can also be provided with a multiplier circuit 314 and an output circuit 316 located in the posterior stage of the oscillation circuit 312. The multiplier circuit 314 generates an oscillation signal obtained by multiplying the frequency of the oscillation signal generated by the oscillation circuit 312. Further, the output circuit 316 outputs the oscillation signal generated by the multiplier circuit 314 or the oscillation signal generated by the oscillation circuit 312 to the CPU 320. The oscillation circuit 312, the multiplier circuit 314, and the output circuit 316 can operate in a differential manner.

The CPU 320 performs a variety of types of arithmetic processing and control processing using the oscillation signal input from the oscillation module 310 as a clock signal in accordance with the program stored in the ROM 340 and so on. Specifically, the CPU 320 performs a variety of processes corresponding to the operation signal from the operation section 330, a process of controlling the communication section 360 for performing data communication with external devices, a process of transmitting a display signal for making the display section 370 display a variety of types of information, and so on.

The operation section 330 is an input device constituted by operation keys, button switches, and so on, and outputs the operation signal corresponding to the operation by the user to the CPU 320.

The ROM 340 stores the programs, data, and so on for the CPU 320 to perform the variety of types of arithmetic processing and control processing.

The RAM 350 is used as a working area of the CPU 320, and temporarily stores, for example, the programs and the data retrieved from the ROM 340, the data input from the operation section 330, and the calculation result obtained by the CPU 320 performing operations in accordance with the variety of types of programs.

The communication section 360 performs a variety of types of control for achieving the data communication between the CPU 320 and the external devices.

The display section 370 is a display device formed of a liquid crystal display (LCD) or the like, and displays a variety of types of information based on the display signal input from the CPU 320. The display section 370 can also be provided with a touch panel, which functions as the operation section 330.

By applying, for example, the oscillation circuit 100 according to the embodiment described above as the oscillation circuit 312, or by applying, for example, the oscillation module 1 according to the embodiment described above as the oscillation module 310, it is possible to realize the electronic apparatus high in reliability.

As such an electronic apparatus 300, a variety of electronic apparatuses can be adopted, and there can be cited, for example, a network apparatus such as an optical transmission device using an optical fiber or the like, a broadcast apparatus, a communication apparatus used in an artificial satellite or a base station, a GPS (global positioning system) module, a personal computer (e.g., a mobile type personal computer, a laptop personal computer, and a tablet personal computer), a mobile terminal such as a smartphone or a cellular phone, a digital camera, an inkjet ejection device (e.g., an inkjet printer), a storage area network apparatus such as a router or a switch, a local area network apparatus, a base station apparatus for a mobile terminal, a television set, a video camera, a video cassette recorder, a car navigation system, a real-time clock device, a pager, a personal digital assistance (including one having a communication function), an electronic dictionary, an electronic calculator, an electronic game machine, a gaming controller, a word processor, a workstation, a picture phone, a security television monitor, an electronic binoculars, a POS (point of sale) terminal, a medical instrument (e.g., an electronic thermometer, a blood pressure monitor, a blood glucose monitor, an electrocardiograph, ultrasonic diagnostic equipment, and an electronic endoscope), a fish finder, a variety of measuring instruments, gauges (e.g., gauges for cars, aircrafts, and boats and ships), a flight simulator, a head-mount display, a motion tracer, a motion tracker, a motion controller, and a pedestrian dead reckoning (PDR) system.

As an example of the electronic apparatus 300 according to the present embodiment, there can be cited a transmission device using the oscillation module 310 described above as a reference signal source, and functioning as, for example, a terminal base station device for communicating with terminals wirelessly or with wire. By applying, for example, the oscillation module 1 according to the embodiment described above as the oscillation module 310, it is also possible to realize the electronic apparatus 300 which can be used for, for example, a communication base station, which is higher in frequency accuracy than ever before, and for which high performance and high reliability are required.

Further, as another example of the electronic apparatus 300 according to the present embodiment, it is possible to adopt a communication device in which the communication section 360 receives an external clock signal, and the CPU 320 (the processing section) includes a frequency control section for controlling the frequency of the oscillation module 310 based on the external clock signal and the output signal of the oscillation module 310.

### 3. Moving Object

FIG. 20 is a diagram (a top view) showing an example of a moving object according to the present embodiment. The moving object 400 shown in FIG. 20 is configured to include an oscillation module 410, controllers 420, 430, and 440 for performing a variety of types of control such as an engine system, a brake system, or a keyless entry system, a battery 450, and a backup battery 460. It should be noted that the moving object according to the present embodiment can have a configuration obtained by eliminating some of the constituents (sections) shown in FIG. 20, or adding other constituents thereto.

The oscillation module 410 is provided with an oscillation circuit (not shown) provided with a SAW filter (not shown), and generates the oscillation signal with a frequency based on the resonance frequency of the SAW filter.

Further, the oscillation module 410 can also be provided with a multiplier circuit and an output circuit located in the posterior stage of the oscillation circuit. The multiplier circuit generates an oscillation signal obtained by multiplying the frequency of the oscillation signal generated by the oscillation circuit. Further, the output circuit outputs the oscillation signal generated by the multiplier circuit or the oscillation signal generated by the oscillation circuit. The oscillation circuit, the multiplier circuit, and the output circuit can operate in a differential manner.

The oscillation signal output by the oscillation module 410 is supplied to the controllers 420, 430, and 440, and is used as, for example, a clock signal.

The battery 450 supplies the oscillation module 410 and the controllers 420, 430, and 440 with electrical power. The backup battery 460 supplies the oscillation module 410 and the controllers 420, 430, and 440 with the electrical power when the output voltage of the battery 450 drops to a level lower than a threshold value.

By applying, for example, the oscillation circuit 100 according to the embodiment described above as the oscillation circuit provided to the oscillation module 410, or by applying, for example, the oscillation module 1 according to the embodiment described above as the oscillation module 410, it is possible to realize the moving object high in reliability.

As such a moving object 400, there can be adopted a variety of types of moving objects, and there can be cited a vehicle (including an electric vehicle), an aircraft such as a jet plane or a helicopter, a ship, a boat, a rocket, an artificial satellite, and so on.

The present disclosure is not limited to the embodiments, but can be implemented with a variety of modifications within the scope or the spirit of the present disclosure.

The embodiments and the modified examples described above are illustrative only, and the present disclosure is not limited to the embodiments and the modified examples. For example, it is also possible to arbitrarily combine any of the embodiments and the modified examples described above with each other.

The present disclosure includes configurations (e.g., configurations having the same function, the same way, and the same result, or configurations having the same object and the same advantage) substantially the same as the configuration described as the embodiment of the present disclosure. Further, the present disclosure includes configurations obtained by replacing a non-essential part of the configuration described as the embodiment of the present disclosure. Further, the present disclosure includes configurations providing the same functions and advantages and configurations capable of achieving the same object as the configuration described as the embodiment of the present disclosure. Further, the present disclosure includes configurations obtained by adding known technologies to the configuration described as one of the embodiments of the present disclosure.

What is claimed is:

1. An oscillation module comprising:
a SAW filter; and
a package adapted to house the SAW filter,
wherein one end of the SAW filter is fixed to the package.

2. The oscillation module according to claim 1, wherein:
the SAW filter includes a first interdigital transducer IDT, a second interdigital transducer IDT, a first input port connected to the first IDT, a second input port connected to the first IDT, a first output port connected to the second IDT, a second output port connected to the second IDT,
the first input port, the second input port, the first output port, and the second output port are disposed in the one end, and
the first IDT and the second IDT are disposed in a portion of the SAW filter other than the one end part.

3. The oscillation module according to claim 2, wherein:
the first input port, the second input port, the first output port, and the second output port are arranged along a first side of the SAW filter in a plan view.

4. The oscillation module according to claim 3, wherein:
the first input port and the second input port are disposed at equal distances from the first side, and the first output port and the second output port are disposed at equal distances from the first side in the plan view.

5. The oscillation module according to claim 4, wherein:
the first input port, the second input port, the first output port, and the second output port are disposed at equal distances from the first side in the plan view.

6. The oscillation module according to claim 3, wherein:
the first input port, the second input port, the first output port, and the second output port are arranged in a direction along the first side in a first sequential order of the first input port, the first output port, the second output port, and the second input port, or a second sequential order of the first output port, the first input port, the second input port, and the second output port in the plan view.

7. The oscillation module according to claim 3, wherein:
the SAW filter has a rectangular shape in the plan view, and
the first side is a long side.

8. The oscillation module according to claim 3, wherein:
the SAW filter has a rectangular shape in the plan view, and
the first side is a short side.

9. The oscillation module according to claim 2, wherein:
a length of a first interconnection adapted to connect the first IDT and the first input port and a length of a second interconnection adapted to connect the first IDT and the second input port are substantially equal to each other.

10. The oscillation module according to claim 2, wherein:
a length of a first interconnection adapted to connect the second IDT and the first output port and a length of a second interconnection adapted to connect the second IDT and the second output port are substantially equal to each other.

11. The oscillation module according to claim 1, further comprising:
an integrated circuit to be connected to the SAW filter,
wherein at least a part of the SAW filter overlaps with the integrated circuit in a plan view.

12. The oscillation module according to claim 11, wherein:
the SAW filter overlaps the integrated circuit in a portion other than the one of the end parts in a plan view.

13. An electronic apparatus comprising:
the oscillation module according to claim 1.

14. A moving object comprising:
the oscillation module according to claim 1.
